(19) United States
(12) Patent Application Publication
(10) Pub. No.: US 2013/0075822 A1
(43) Pub. Date: Mar. 28, 2013

(54) STRUCTURES AND METHODS OF SELF-ALIGNED GATE FOR SB-BASED FETS

(71) Applicants: Han-Chieh Ho, Kaohsiung City (TW); Heng-Kuang Lin, Zhubei City (TW)

(72) Inventors: Han-Chieh Ho, Kaohsiung City (TW); Heng-Kuang Lin, Zhubei City (TW)

(21) Appl. No.: 13/242,131

(22) Filed: Sep. 23, 2011

(51) Int. Cl. H01L 27/088; H01L 21/20

(52) U.S. Cl. 257/368; 438/478; 257/E27.06; 257/E21.09

(57) ABSTRACT

The advantage of narrow-bandgap Sb-based devices is the realization of high-frequency operation with much lower power consumption. However, some properties such as chemical stability are the key issues for developing Sb-based devices. The process temperature of the ion implant and thermal annealing in conventional silicon industry is over 1000° C. Sb-based materials are easily degraded at temperature greater 300° C. Thus, this invention provides three processes for self-aligned gate with lower process temperature (<300° C.) to reduce device access region resistance and maintain material quality.

### FIELD OF THE INVENTION

The present invention relates semiconductor fabrication, and more specifically to the structure and process for self-aligned gates that can be applied to antimonide-based lower power consumption and high-performance FETs.

### BACKGROUND OF THE INVENTION

In integrated circuits, a large number of individual circuit devices, such as CMOS, NMOS or PMOS Field-Effect-Transistor, are all formed on a single chip. Typically, feature sizes of such integrated circuits may be continuously reduced by an introduction of a new circuit to improve the performance of speed and power dissipation. The performance of signal processing is enhanced effectively by an increase in switching speed, which can be carried out by a reduction in the dimension of the unit cell. The transient current of the CMOS Field-Effect-Transistor that is generated by a switch from a logic low to a logic high can be significantly reduced by a decrease in switching time period. With a reduction in the channel length of FET, it needs to reduce the thickness of a gate dielectric to gain full capacitive coupling between a gate electrode and a channel layer, thereby forming an appropriate control over conductive channels when a control voltage applies to the gate electrode. For a device in a high-density integrated circuit, it typically has a channel length of 0.18 μm or less and a gate dielectric thickness of 2˜5 nm or less.

Recently, there has been considerable interest in the potential of III-V FET materials for advanced logic applications. III-V high-speed, low-power complementary logic technology could enhance digital circuit functionality and sustain Moore's law for additional generations. When these technologies are utilized in mixed signal circuits, a significant reduction in power consumption could also be obtained. Hetero-structure field-effect transistors (HFETs) made of antimonide-based compound semiconductor materials have intrinsic performance advantages due to the attractive electron and hole transport properties, low ohmic contact resistances, and unique band-lineup design flexibility within this material system. These advantages can be particularly exploited in applications where high-speed operation and low-power consumption are essential. Sb-based hetero-structure devices have intrinsic high-speed and low-power consumption advantages that can provide the enabling technology needed for these applications, which include space-based communications, imaging, sensing, identification, high-data-rate transmission, micro-air-vehicles, wireless and other portable systems. The low dc power consumption of Sb-based HEMTs is also attractive for large-scale active-array space-based radar applications which are particularly power-constrained.

Moreover, for devices with deep sub-micron gate length, source and drain access resistance becomes a serious issue to degrade device performance, especially in the applications of high-frequency devices. In typical Si technology, self-aligned gate using ion implantation and thermal annealing processes is the most conventional and frequently-chosen approach to avoid the influence of access resistance on the device performance. However, the self-aligned gate technique requires process temperature well above 1000° C. to fix the damages caused by the ion implantation process. Sb-based materials have potential to develop low-power and high-frequency devices and MMICs. However, chemical activity of these materials is higher than GaAs- or InP-based materials to increase the difficulty in device/IC fabrication. For example, if the Sb-based materials are exposed at the temperature above 300° C., relative material quality indexes such as mobility, defect density . . . etc are easily degraded.

Based-on the above description, the present invention proposes self-aligned gate processes that can simultaneously minimize thermal impact and chemical reaction to the Sb-based materials at the temperature below 300 for reducing source and drain access resistance and in order to completely realize their potential in high-speed low-power applications.

### SUMMARY OF THE INVENTION

One objective of the present invention is to provide some kinds processes for forming a self-aligned gate which are compatible with antimonide materials. These self-aligned gates are suitable for conventional Sb-based HEMTs and Sb-based MISFETs.

In order to achieve the objectives, the present invention is to provide a structure of Sb-based FETs. The structure comprises a Sb-based epitaxial layer, which comprises a buffer layer, a channel layer and a gate dielectric layer, wherein the channel layer is formed on the buffer layer and the gate dielectric layer is formed on the channel layer; a metallic gate layer formed on the dielectric layer; a spacer formed on the gate dielectric layer; a passivation layer formed on the metallic gate layer, wherein the metallic gate layer, the spacer and the passivation layer construct a self-aligned gate.

The structure further comprises a patterned epitaxial layer and a patterned ohmic metal layer formed on the Sb-based epitaxial layer and by sidewall of the spacer. The structure further comprises an epitaxial layer formed on the Sb-based epitaxial layer except the self-aligned gate region, and a patterned ohmic metal layer formed on the epitaxial layer and by sidewall of the spacer.

In order to achieve the objectives, the present invention is to provide another structure of Sb-based FETs. The structure comprises a Sb-based epitaxial layer; a metallic gate layer formed on the gate dielectric layer of the Sb-based epitaxial layer; a second dielectric layer formed on the metallic gate layer, wherein the metallic gate layer and the second dielectric layer construct a self-aligned gate, wherein the self-aligned gate has the same region with that of the channel layer and the gate dielectric layer of the Sb-based epitaxial layer.

The structure further comprises a spacer formed on sidewall of the self-aligned gate, and a patterned epitaxial layer and a patterned ohmic metal layer formed on the Sb-based epitaxial layer and by sidewall of the spacer.

In order to achieve the objectives, the present invention also provides some methods for fabricating Sb-based MISFETs. First, a patterned first photo resist layer is formed on a Sb-based epitaxial layer to create an opening. A second dielectric layer is formed to cover upper surface and sidewall of the patterned first photo resist layer and the upper surface of the Sb-based epitaxial layer below the opening. The second dielectric layer is selectively removed to form a spacer layer on sidewall of the patterned first photo resist layer. A metal material layer is formed on the patterned first photo resist layer and the spacer to cover the patterned first photo resist layer, and fill into the opening. The metal material layer is selectively removed to form a metallic gate layer on the Sb-based epitaxial layer and connect to sidewall of the spacer. A third dielectric layer is formed on the patterned first photo resist layer, the spacer layer and the metallic gate layer. The third dielectric layer is selectively removed to form a gate passivation layer on the metallic gate layer. The patterned first photo resist layer is removed to form a self-aligned gate.

The method further comprises re-growing an epitaxy material to form an epitaxial layer on the Sb-based epitaxial layer and the self-aligned gate, and followed by conformably forming a metal layer on the epitaxial layer; and selectively removing the epitaxial layer and the metal layer to form a patterned epitaxial layer and a patterned metal layer by sidewall of the spacer for exposing top and upper sidewall portion of the spacer.

The method further comprises selectively removing the Sb-based epitaxial layer to expose sidewall of the gate dielectric layer and the channel layer. The method further comprises forming an epitaxial layer on the Sb-based epitaxial layer except the self-aligned gate region to cover the gate dielectric layer and the channel layer; forming a metal layer on the epitaxial layer and the self-aligned gate; and selectively removing the metal layer to form a patterned ohmic metal layer on the epitaxial layer.

Another methods for fabricating Sb-based MISFETs comprise forming a metal layer on a Sb-based epitaxial layer; forming a first dielectric layer on the metal layer; and removing the first dielectric layer, the metal layer and the Sb-based epitaxial layer except gate area to form a gate structure and expose the channel layer.

The method further comprises forming a second dielectric layer on the gate structure and the channel layer; and the second dielectric layer is selectively removed to form a spacer on side of the gate structure, the gate dielectric layer and the channel layer. Next, re-growing an epitaxy material to form an epitaxial layer on the modulation doping layer and the self-aligned gate is performed, and followed by conformally forming a metal layer on the epitaxial layer; and selectively removing the epitaxial layer and the metal layer to form a patterned epitaxial layer and a patterned metal layer by sidewall of the spacer for exposing top and upper sidewall portion of the spacer.

### BRIEF DESCRIPTION OF THE DRAWINGS

FIGS. 1A and 1B are Sb-based epitaxial layer structures for Metal insulator semiconductor or MISFETs according to the present invention.

FIG. 2 shows a first photo resist layer formed on the Sb-based epitaxial layer structure according to the present invention.

FIG. 3 shows another dielectric layer formed on the Sb-based epitaxial layer structure and the first photo resist layer according to the present invention.

FIG. 4 shows a spacer layer formed on the sidewall of the patterned first photo resist layer according to the present invention.

FIG. 5 shows a metal material layer formed on the patterned first photo resist layer and the spacer according to the present invention.

FIG. 6 shows a gate metal layer formed on the Sb-based epitaxial layer structure and connected to sidewall of the spacer layer according to the present invention.

FIG. 7 shows a third dielectric layer formed on the patterned first photo resist layer, the spacer layer and the gate metal layer according to the present invention.

FIG. 8 shows a gate passivation layer formed on the gate metal layer according to the present invention.

FIG. 9 shows a self-aligned gate formed on Sb-based epitaxial layer structure according to the present invention.

FIG. 10 shows an epitaxial layer and a metal layer formed on Sb-based epitaxial layer structure according to the present invention.

FIG. 11 shows a photo-resist layer coated on the metal layer according to the present invention.

FIG. 12 shows forming a thinned photo-resist layer on the metal layer according to the present invention.

FIG. 13 shows forming a patterned epitaxial layer and a patterned ohmic metal layer by lower sidewall portion of the spacer and on the Sb-based epitaxial layer structure according to the present invention.

FIG. 14 shows selectively removing the Sb-based epitaxial layer structure according to the present invention.

FIG. 15 shows forming an epitaxial layer on the Sb-based epitaxial layer structure except the self-aligned gate region according to the present invention.

FIG. 16 shows forming a metal layer on the epitaxial layer and the self-aligned gate according to the present invention.

FIG. 17 shows forming a photo-resist layer on the metal layer according to the present invention.

FIG. 18 shows forming a thinned photo-resist layer on the metal layer according to the present invention.

FIG. 19 shows forming a patterned ohmic metal layer on the epitaxial layer and by (adjacent) sidewall of the spacer according to the present invention.

FIG. 20 shows forming a metal layer and a dielectric layer on the Sb-based epitaxial layer according to the present invention.

FIG. 21 shows forming a patterned photo-resist pattern on the dielectric layer to define a gate area according to the present invention.

FIG. 22 shows forming a gate structure on a Sb-based epitaxial layer structure according to the present invention.

FIG. 23 shows forming another dielectric layer on the gate structure and the channel layer structure according to the present invention.

FIG. 24 shows forming a sidewall spacer on side of the gate, the gate dielectric layer and the channel layer according to the present invention.

FIG. 25 shows forming an epitaxy material and a metal layer on the Sb-based epitaxial layer structure and the self-aligned gate according to the present invention.

FIG. 26 shows forming a photo-resist layer on the metal layer according to the present invention.

FIG. 27 shows forming a thinned photo-resist layer on the metal layer according to the present invention.

FIG. 28 shows forming a patterned epitaxial layer and a patterned ohmic metal layer by lower sidewall portion of the spacer and on the Sb-based epitaxial layer structure according to the present invention.

### DETAILED DESCRIPTION OF THE PREFERRED EMBODIMENT

The present invention and embodiments are now described in detail. In the diagrams and descriptions below, the same symbols are utilized to represent the same or similar elements. The possible embodiments of the present invention are described in illustrations. Additionally, all elements of the drawings are not depicted in proportional sizes but in relative sizes.

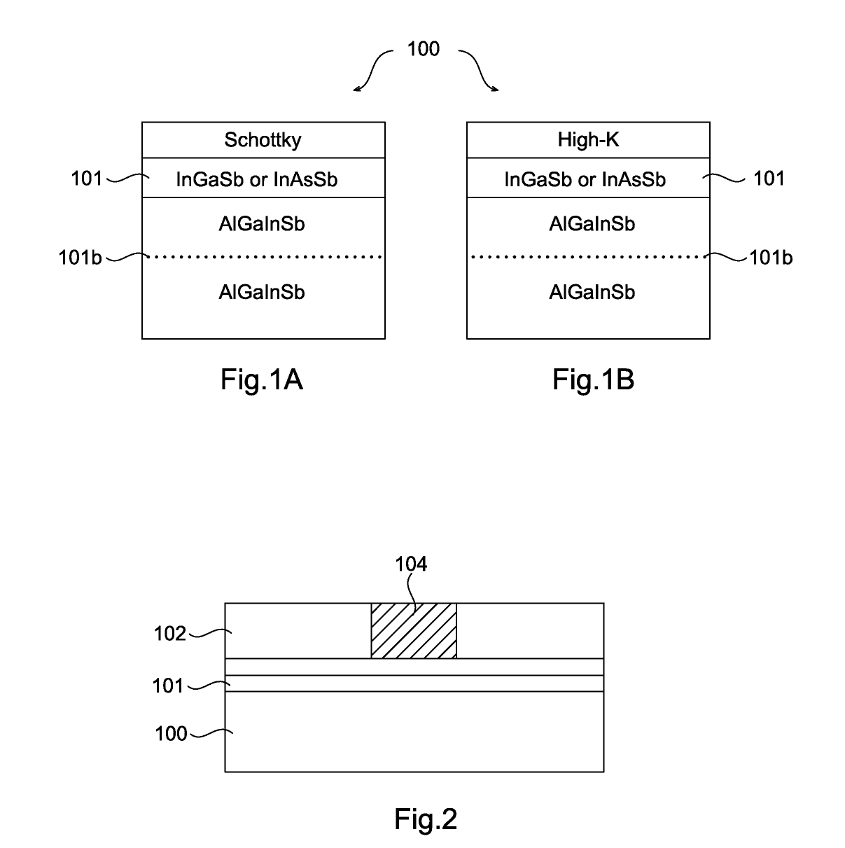

Referring to FIGS. 1A and 1B, they show a Sb-based epitaxial layer structures for a Depletion mode or an Enhancement mode MISFET according to the present invention. Two kinds of layer structures of FIG. 1A and FIG. 1B can be used, which is applied for conventional Sb-based HEMTs and for Sb-based MISFETs (MISFETs) respectively. In FIG. 1A and FIG. 1B, they show a Sb-based epitaxial layer structure 100 with a tri-layer of a D-mode MISFET, wherein the tri-layer structure comprises a first epitaxial layer, a second epitaxial layer and a third epitaxial layer. The first epitaxial layer is formed by the material comprising the combination of Al(aluminum)-Ga(gallium)-In(indium)-Sb(antimony) as a buffer layer; the second epitaxial layer is formed by the material including the combination of In—Ga—Sb or In—As(arsenic)-Sb formed on the buffer layer as a channel layer, and the third epitaxial layer is formed by a Schottky barrier layer or a high-k dielectric layer as a gate dielectric layer, respectively. An n- or p- modulation doping 101b is formed in the buffer layer and at a specified depth beneath the channel The depth of the n- or p-modulation doping 101b may be adjusted depending on the requirement in device performance. In an E-mode MISFET, no n- or p- modulation doping is formed in the buffer layer. Moreover, whichever D-mode or E-mode MISFET is to be made, a channel layer can be made by either InₓGa₁₋ₓSb or InAsₓSb₁₋ , wherein x is equal to 0˜1.0. The two InGaSb or InAsSb channel layers, simultaneously have excellent electron and hole mobilities. The buffer layer can be made by AlₓGa_{y}In_{z}Sb, wherein x+y+z is equal to 1.0. Moreover, the tri-layer structure may be formed on a substrate which is formed by the material comprising Si, InP or GaAs.

The present invention provides three kinds processes for forming self-aligned gates which are compatible with antimonide materials. These self-aligned gates are suitable for conventional Sb-based HEMTs and Sb-based MISFETs (MISFETs). The process flow for fabricating self-aligned gates for Sb-based FETs describes below accompanying with the following drawings.

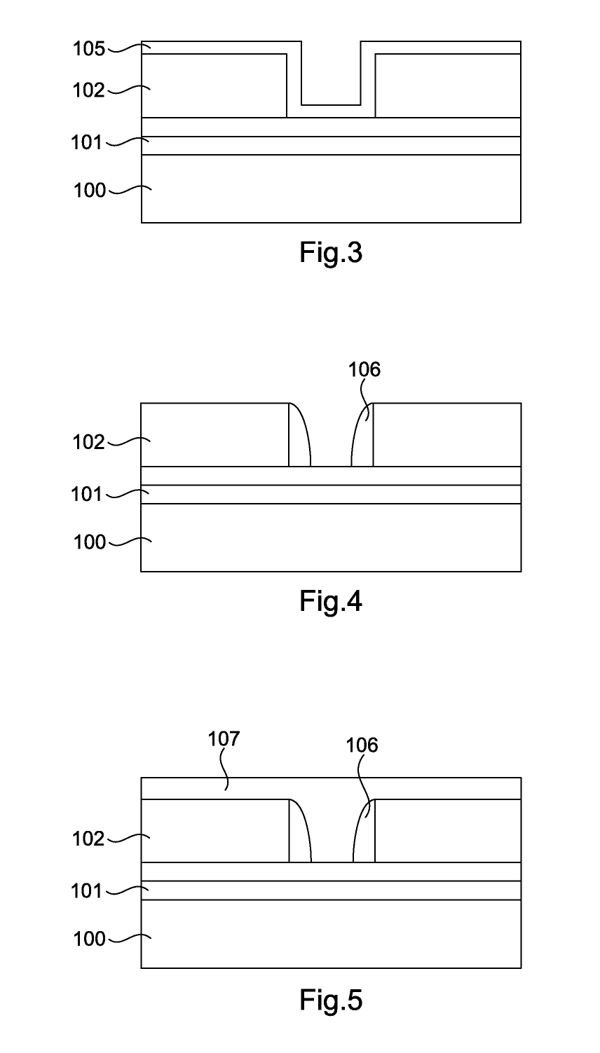

Firstly, a photo-resist 102 is formed on a Sb-based epitaxial layer structure 100, and then an opening is created to define a gate area 104 by using a photolithography process, shown in FIG. 2. Subsequently, a dielectric layer 105, for example SiOₓ, is formed (deposited) to cover the upper surface and sidewall of the photo resist 102 and the upper surface of the Sb-based epitaxial layer structure 100 below the opening 104, shown in FIG. 3. Next, after selective removal of the dielectric layer 105 by a dry etching process, a spacer layer 106 is formed on the sidewall of the photo resist 102, shown in FIG. 4. Thickness of the spacer layer 106 is subsequently equal to that of the patterned photo resist 102. Then, a metal material layer 107 is formed (deposited) on the patterned photo resist 102 and the spacer 106 to cover the patterned photo resist 102 and the spacer 106, and fill into the opening, shown in FIG. 5.

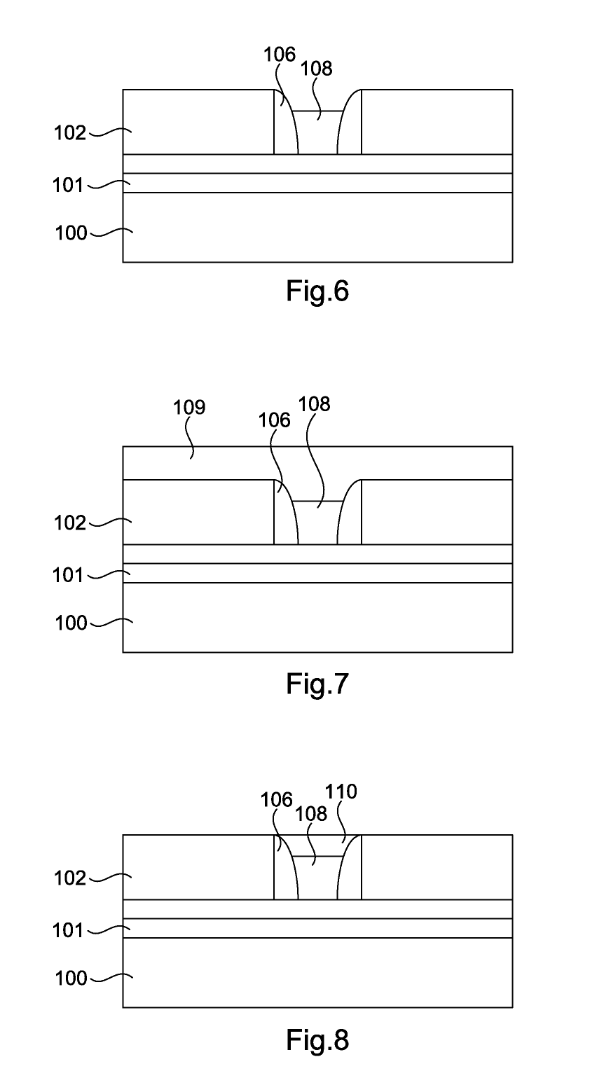

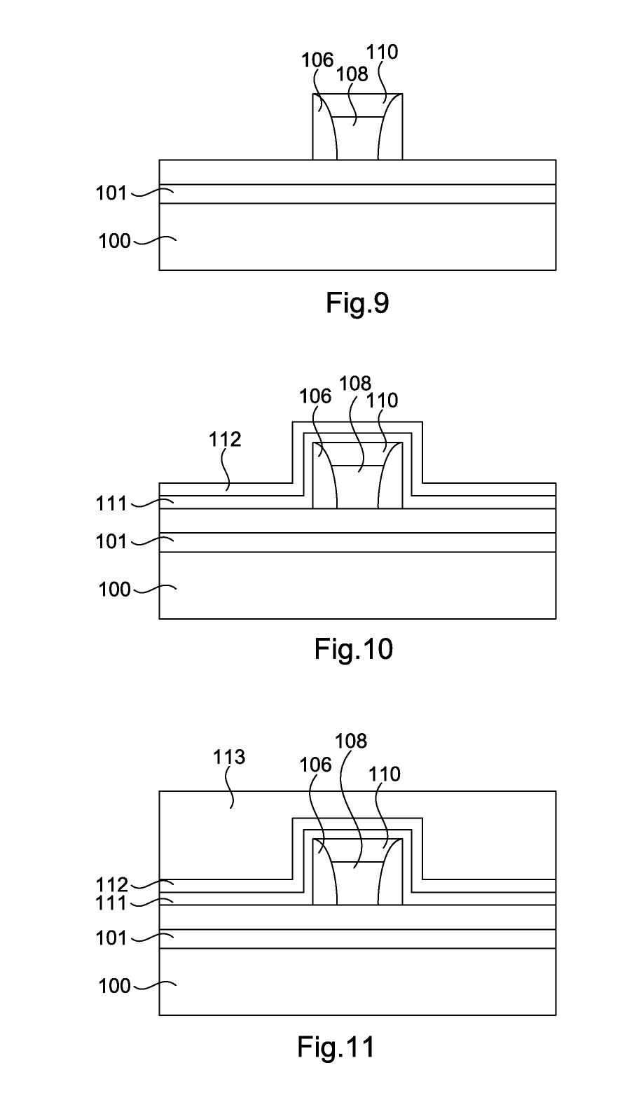

Similarly, after selective removal of the metal material layer 107 by a dry etching process, a gate metal (metallic gate) layer 108 is formed on the Sb-based epitaxial layer structure 100 and connected to two sidewall of the spacer layer 106, shown in FIG. 6. Thickness of the gate metal layer 108 is smaller than that of the spacer layer 106, and therefore creating a recess on the gate metal layer 108. Next, a photo resist layer 109 with good liquidity, for example BCB (Benezocy-clobutene), is formed (coated) on (to cover) the photo resist 102, the spacer layer 106 and the gate metal layer 108 and filled into the recess, shown in FIG. 7. After selective removal of the photo resist layer 109 by a dry etching process for stopping on the photo resist layer 102 to form a gate passivation layer 110 on to cover the gate metal layer 108 is finished, the passivation layer 110 has the same level with the photo resist layer 102, shown in FIG. 8. Thickness of the gate metal layer 108 plus the passivation layer 110 is substantially equal to that of the spacer layer 106. Subsequently, the photo resist layer 102 is removed by a stripping process to form a self-aligned gate on the Sb-based epitaxial layer structure, shown in FIG. 9.

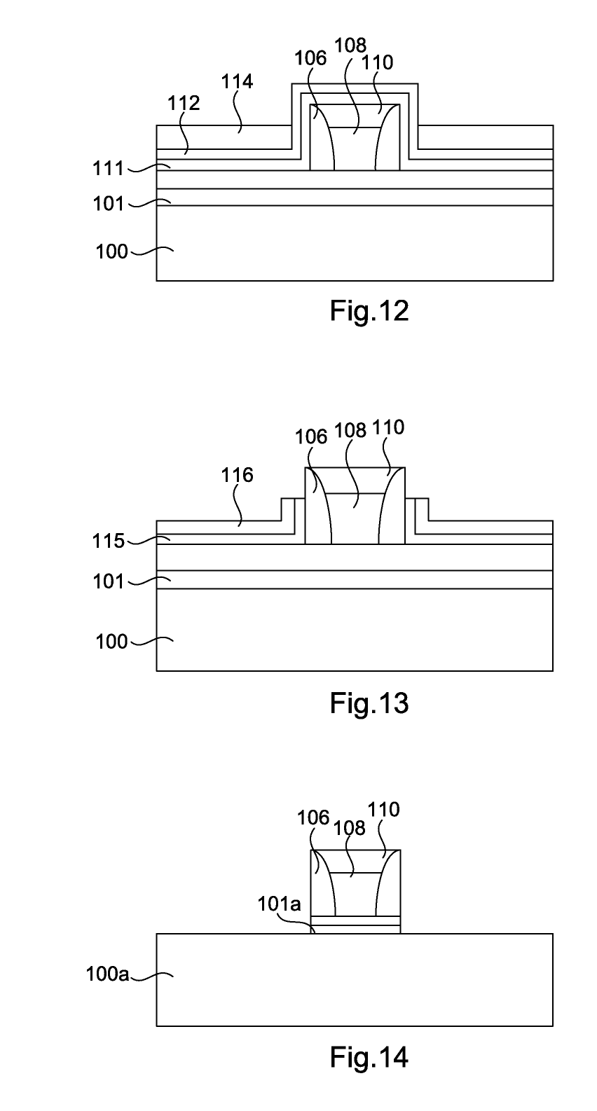

Next, it is performed a process of re-growing an epitaxy material to form an epitaxial layer 111 with high doping and low resistances on the Sb-based epitaxial layer structure 100 and the self-aligned gate, and followed by conformally forming (depositing) a metal layer 112 on the epitaxial layer 111 for ohmic contacts, shown in FIG. 10. A photo-resist layer 113 is then coated on the metal layer 112, shown in FIG. 11. Subsequently, the photo-resist layer 113 is thinned down below top of the gate to expose upper surface of the metal layer 112 and partial sidewall of the metal layer 112, and thereby forming a thinned photo-resist layer 114, shown in FIG. 12. Finally, the re-grown epitaxial layer 111 and the ohmic metal layer 112 exposed by the thinned photo-resist layer 114 are selectively removed at top and partial (upper portion of the) sidewall of the gate to form a patterned (L-shaped) re-grown epitaxial layer 115 and a patterned (L-shaped) ohmic metal layer 116, shown in FIG. 13. Then, stripping residual photo-resist 114 is performed, shown in FIG. 13. Such structure of the FIG. 13 is suitable for the conventional Sb-based HEMTs.

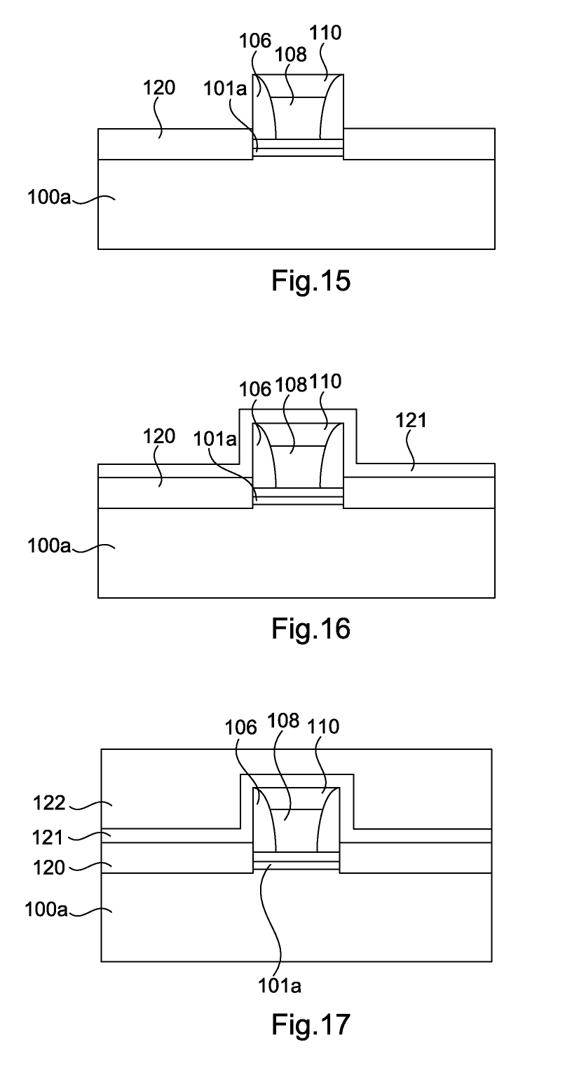

Following, according to another embodiment of the present invention, the process flow for fabricating another self-aligned gate and its related device structure for Sb-based FETs is described below. Based-on the FIG. 9, the Sb-based epitaxial layer structure 100 is selectively remove, for example removing partial the gate dielectric layer and the channel layer by a selectively etching process for stopping lower surface of the channel layer, and thereby exposing sidewall of the channel layer and the gate dielectric layer, shown in FIG. 14. In this process, the Sb-based epitaxial layer structure 100 is removed except the self-aligned gate region until the channel layer removed to form a Sb-based epitaxial layer structure 100a, shown in FIG. 14. In this embodiment, the channel layer 101a and the gate dielectric layer have the same region (length) with the self-aligned gate. Subsequently, an epitaxy material with high doping and low resistances is selectively re-grown at contact area to form an epitaxial layer 120 on the Sb-based epitaxial layer structure 100a except the self-aligned gate region, which covers sidewall of the channel layer 101a, the gate dielectric layer and the spacer 106, shown in FIG. 15. Then, a metal layer 121 is formed (deposited) on the epitaxial layer 120 and the self-aligned gate for ohmic contacts, shown in FIG. 16.

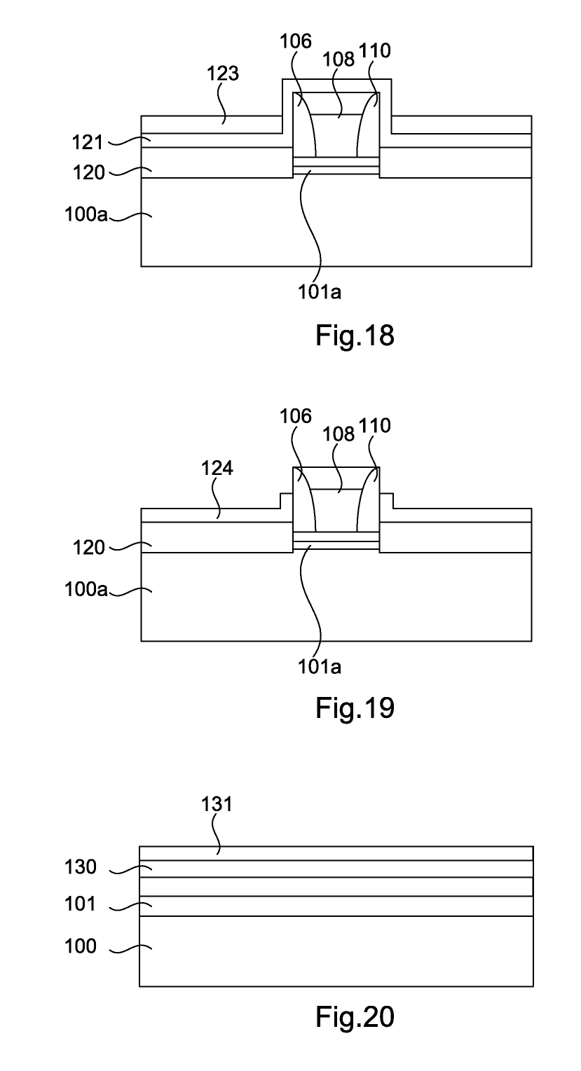

Next, a photo-resist layer 122 is coated on the metal layer 121, shown in FIG. 17. Subsequently, the photo-resist layer 122 is thinned down below top surface of the gate to expose upper surface of the metal layer 121 and partial sidewall of the metal layer 121, and thereby forming a thinned photo-resist layer 123, shown in FIG. 18. Finally, the ohmic metal layer 121 is selectively removed at top and partial sidewall of the gate to form a patterned ohmic metal layer 124 on the epitaxial layer 120 and by two sidewall of the spacer 106 by an etching process to expose upper sidewall of the spacer 106, and then stripping residual photo-resist, shown in FIG. 19. In this embodiment, such structure of the FIG. 19 is suitable for the conventional Sb-based HEMTs and Sb-based MISFETs.

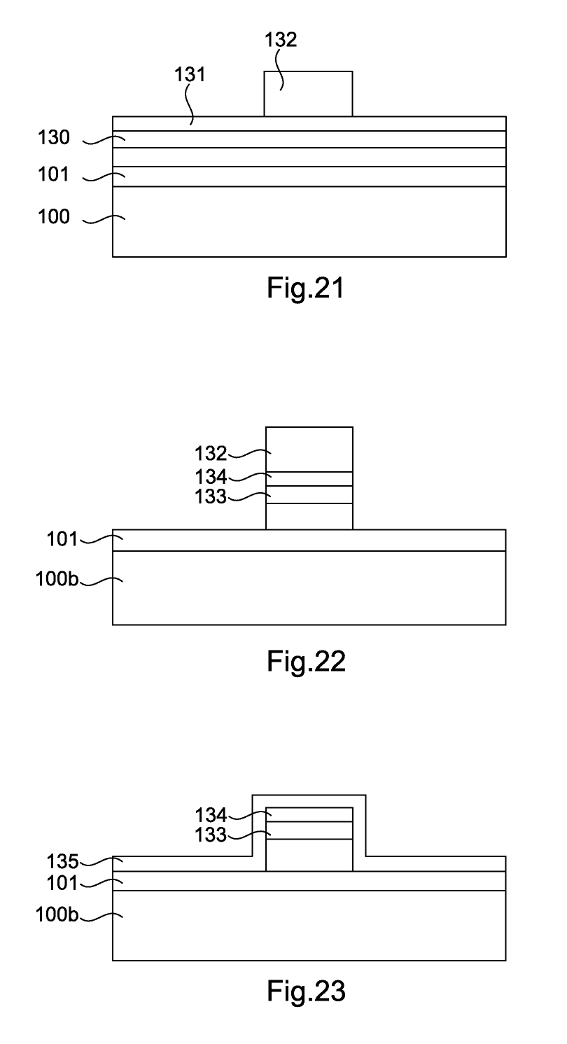

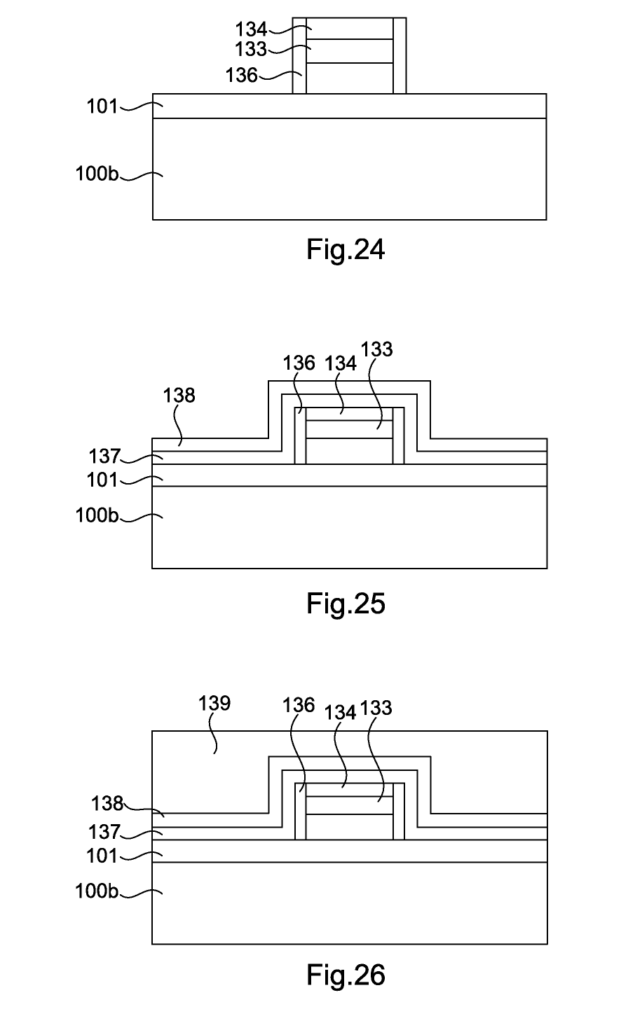

Moreover, according to yet another embodiment of the present invention, the process flow for fabricating a self-aligned gate and its related device structure for Sb-based FETs is provided. Firstly, a metal layer 130 is formed on the Sb-based epitaxial layer structure 100, and then a dielectric layer 131, for example SiNₓ (silicon nitride) or SiOₓ (silicon oxide), is formed on metal layer 130, shown in FIG. 20. Subsequently, a patterned photo-resist pattern 132 is formed on the dielectric layer 131 to define a gate area, shown in FIG. 21. Next, a dry etching process is performed to etch the dielectric layer 131, the metal layer 130 and the Sb-based epitaxial layer structure 100 except the gate area for stopping on the channel layer 101 to form a gate structure on a Sb-based epitaxial layer structure 100b, shown in FIG. 22. In this step, the channel layer 101 is exposed as contact area with other layers at upper portion of the Sb-based epitaxial layer structure 100b. The gate structure comprises a patterned dielectric layer 134 and a gate metal layer 133 formed on the channel layer 101, wherein the patterned dielectric layer and the gate metal layer have the same region with that of the channel layer and the gate dielectric layer. Then, another dielectric layer 135, for example SiNₓ (silicon nitride) or SiOₓ (silicon oxide), is conformally formed (deposited) on the gate structure and the channel layer 101, shown in FIG. 23. The dielectric layer 135 is selectively removed by a dry etching process to remove at top of the gate structure and above the channel layer 101 to form a sidewall spacer 136 on side of the gate, the gate dielectric layer and the channel layer, and thereby forming another new type self-aligned gate, shown in FIG. 24.

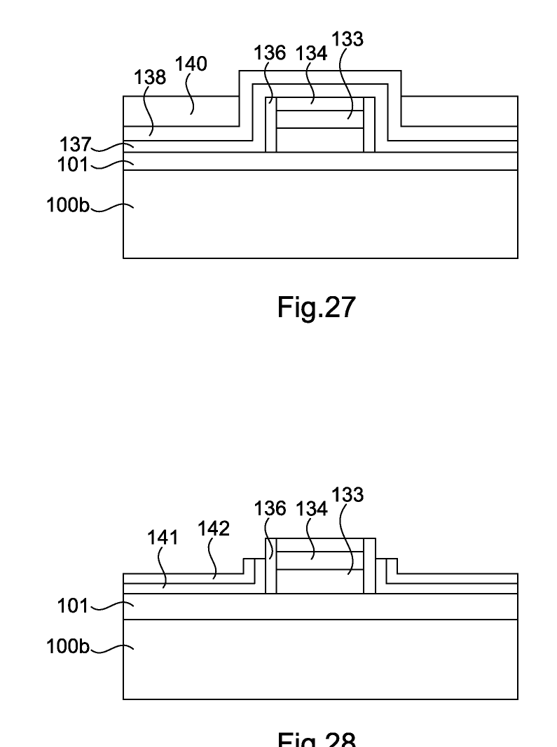

Following, re-growing an epitaxy material with high doping and low resistances on the Sb-based epitaxial layer structure 100b (the channel layer 101) and the self-aligned gate is performed to form an epitaxial layer 137, and followed by conformally forming (depositing) a metal layer 138 on the epitaxial layer 137 for ohmic contacts, shown in FIG. 25. Next, a photo-resist layer 139 is then coated on the metal layer 137, shown in FIG. 26. Subsequently, the photo-resist layer 139 is thinned down below top surface of the gate to expose upper surface of the metal layer 138 and partial sidewall of the metal layer 138, for example by a photo-resist stripping solvent, and thereby forming a thinned photo-resist layer 140, shown in FIG. 27. Finally, the re-grown epitaxial layer 137 and the ohmic metal layer 138 are selectively removed at top surface and partial sidewall of the gate to form a patterned re-grown epitaxial layer 141 and a patterned ohmic metal layer 142 by (adjacent) lower sidewall portion of the spacer 136, and thereby exposing top surface and upper sidewall portion of the spacer 136, shown in FIG. 28. Stripping residual photo-resist is then performed, shown in FIG. 28. Such structure of the FIG. 28 is suitable for the conventional Sb-based HEMTs and Sb-based MISFETs.

To summarize, according to above-mentioned of descriptions, advantages of this present invention comprises:
1. A self-aligned gate fabricating process of the present invention can reduce source and drain access resistance in the FETs and enhance high-frequency performance.
2. Ion implant process and high temperature annealing process (above 1000° C.). are without needed in the self-aligned gate and its related device fabricating process, and thereby it does not easily damage antimonide materials.
3. Process temperature in the whole process flow may be designed much less than 300 to avoid potential degradation of the antimonide materials.

As will be understood by persons skilled in the art, the foregoing preferred embodiment of the present invention illustrates the present invention rather than limiting the present invention. Having described the invention in connection with a preferred embodiment, modifications will be suggested to those skilled in the art. Thus, the invention is not to be limited to this embodiment, but rather the invention is intended to cover various modifications and similar arrangements included within the spirit and scope of the appended claims, the scope of which should be accorded the broadest interpretation, thereby encompassing all such modifications and similar structures. While the preferred embodiment of the invention has been illustrated and described, it will be appreciated that various changes can be made without departing from the spirit and scope of the invention.

What is claimed is:

1. A structure of Sb-based FETs, comprising:
a Sb-based epitaxial layer, which comprises a buffer layer, a channel layer and a gate dielectric layer, wherein said channel layer is formed on said buffer layer and said gate dielectric layer is formed on said channel layer;
a gate metal layer formed on said gate dielectric layer;
a spacer formed on said gate dielectric layer; and
a passivation layer formed on said gate metal layer, wherein said gate metal layer, said spacer and said passivation layer construct a self-aligned gate.

2. A structure in claim 1, wherein material of said buffer layer is a combination of Al(aluminum), Ga(gallium), In(indium) and Sb(antimony), wherein said combination is AlₓGa_{y}In_{z}Sb and x+y+z is equal to 1.0.

3. The structure in claim 2, wherein material of said channel layer is a combination of In(indium), Ga(gallium) and Sb(antimony) or In(indium), As(arsenic) and Sb(antimony), wherein said combination is InₓGa₁₋ₓSb or InAsₓSb₁₋ₓ, wherein x is between to 0 and 1.0.

4. The structure in claim 1, further comprising a patterned epitaxial layer and a patterned ohmic metal layer formed on said Sb-based epitaxial layer and by sidewall of said spacer.

5. The structure in claim 1, wherein said gate dielectric layer and said channel layer have the same region with that of said self-aligned gate.

6. The structures in claim 5, wherein material of said buffer layer is a combination of Al(aluminum), Ga(gallium), In(indium) and Sb(antimony), wherein said combination is AlₓGa_{y}In_{z}Sb and x+y+z is equal to 1.0.

7. The structures in claim 6, wherein material of said channel layer is a combination of In(indium), Ga(gallium) and Sb(antimony) or In(indium), As(arsenic) and Sb(antimony), wherein said combination is InₓGa₁₋ₓSb or InAsₓSb₁₋ₓ, wherein x is between to 0 and 1.0.

8. A structure in claim 5, further comprising a second epitaxial layer formed on said Sb-based epitaxial layer except said self-aligned gate region, and a patterned ohmic metal layer formed on said second epitaxial layer and by sidewall of said spacer.

9. A structure of Sb-based FETs, comprising:
a Sb-based epitaxial layer, which comprises a buffer layer, a channel layer and a gate dielectric layer, wherein said channel layer is formed on said buffer layer and said gate dielectric layer is formed on said channel layer;
a gate metal layer formed on said dielectric layer; and
a second dielectric layer formed on said gate metal layer, wherein said gate metal layer and said second dielectric layer construct a self-aligned gate, wherein said self-aligned gate has the same region with that of said channel layer and said gate dielectric layer

10. A structure in claim 9, wherein material of said buffer layer is a combination of Al(aluminum), Ga(gallium), In(indium) and Sb(antimony), wherein said combination is AlₓGa_{y}In_{z}Sb and x+y+z is equal to 1.0.

11. The structure in claim 10, wherein material of said channel layer is a combination of In(indium), Ga(gallium) and Sb(antimony) or In(indium), As(arsenic) and Sb(antimony), wherein said combination is InₓGa₁₋ₓSb or InAsₓSb₁₋ₓ, wherein x is between to 0 and 1.0.

12. The structure in claim 9, further comprising a spacer formed on sidewall of said self-aligned gate.

13. The structure in claim 12, further comprising a patterned epitaxial layer and a patterned ohmic metal layer formed on said Sb-based epitaxial layer and by sidewall of said spacer.

14. A method for fabricating Sb-based FETs, comprising:
forming a patterned first photo resist layer on a Sb-based epitaxial layer to create an opening, wherein said Sb-based epitaxial layer comprises a buffer layer, a channel layer and a gate dielectric layer, wherein said channel layer is formed on said buffer layer and said gate dielectric layer is formed on said channel layer;
forming a second dielectric layer to cover upper surface and sidewall of said patterned first photo resist layer and upper surface of said Sb-based epitaxial layer below said opening;
selectively removing said second dielectric layer to form a spacer on sidewall of said patterned first photo resist layer;
forming a metal material layer on said patterned first photo resist layer and said spacer to cover said patterned first photo resist layer, and fill into said opening;
selectively removing said metal material layer to form a gate metal layer on said Sb-based epitaxial layer and connect to sidewall of said spacer;
forming a third dielectric layer on said patterned first photo resist layer, said spacer and said gate metal layer;
selectively removing said third dielectric layer to form a gate passivation layer on said gate metal layer; and
removing said patterned first photo resist layer to form a self-aligned gate.

15. The method in claim 14, further comprising:
re-growing an epitaxy material to form a second epitaxial layer on said Sb-based epitaxial layer and said self-aligned gate, and followed by forming a second metal layer on said second epitaxial layer; and
selectively removing said second epitaxial layer and said second metal layer to form a patterned second epitaxial layer and a patterned second metal layer by sidewall of said spacer for exposing top surface and upper sidewall portion of said spacer.

16. The method in claim 14, further comprising selectively removing said Sb-based epitaxial layer to expose sidewall of said gate dielectric layer and said channel layer.

17. The method in claim 16, further comprising:
forming a second epitaxial layer on said Sb-based epitaxial layer except said self-aligned gate region to cover said gate dielectric layer and said channel layer;
forming a second metal layer on said epitaxial layer and said self-aligned gate; and
selectively removing said second metal layer to form a patterned ohmic metal layer on said second epitaxial layer.

18. A method for fabricating Sb-based FETs, comprising:
forming a metal layer on a Sb-based epitaxial layer, wherein said Sb-based epitaxial layer comprises a buffer layer, a channel layer and a gate dielectric layer, wherein said channel layer is formed on said buffer layer and said gate dielectric layer is formed on said channel layer;
forming a first dielectric layer on said metal layer; and
removing said first dielectric layer, said metal layer and said Sb-based epitaxial layer except gate area to form a gate structure and expose said channel layer.

19. The method in claim 18, further comprising:
forming a second dielectric layer on said gate structure and said channel layer; and
selectively removing said second dielectric layer to form a spacer on side of said gate structure, said gate dielectric layer and said channel layer.

20. The method in claim 19, further comprising:
re-growing an epitaxy material to form a second epitaxial layer on said channel layer and said self-aligned gate, and followed by forming a second metal layer on said second epitaxial layer; and
selectively removing said second epitaxial layer and said second metal layer to form a patterned second epitaxial layer and a patterned second metal layer by sidewall of said spacer for exposing top surface and upper sidewall portion of said spacer.
